(19) United States
(12) Patent Application Publication
(10) Pub. No.: US 2026/0188219 A1
(43) Pub. Date: Jul. 2, 2026

(54) PIXEL AND DISPLAY DEVICE INCLUDING THE PIXEL

(71) Applicant: LG Display Co., Ltd., Seoul (KR)

(72) Inventors: Youngjae LEE, Paju-si (KR); Taekyeong LEE, Paju-si (KR)

(73) Assignee: LG Display Co., Ltd., Seoul (KR)

(21) Appl. No.: 19/290,722

(22) Filed: Aug. 5, 2025

(30) Foreign Application Priority Data
Dec. 30, 2024 (KR) 10-2024-0200116

(51) Int. Cl. G09G 3/3233; G09G 3/3266; H10K 59/124

(52) U.S. Cl. CPC G09G 3/3233; H10K 59/124; G09G 3/3266; G09G 2300/0819; G09G 2300/0852; G09G 2300/0861; G09G 2310/0286; G09G 2320/0219

(57) ABSTRACT

Embodiments relate to a pixel and a display device including the pixel. The pixel includes a light-emitting element, a driving transistor connected between a high-potential driving voltage line and a first node, with a gate electrode connected to a second node, a switching transistor connected between a data line and the second node, with a gate electrode receiving a first scan signal, an initialization transistor connected between a reference voltage line and the second node, with a gate electrode receiving a second scan signal, a first light-emission transistor connected between the high-potential driving voltage line and the driving transistor, with a gate electrode receiving a first emission signal, a second light-emission transistor connected between the first node and the light-emitting element, with a gate electrode receiving a second emission signal, a first capacitor connected between the first node and the second node, a second capacitor with one electrode connected to the first node, and a compensation transistor connected between the second capacitor and the reference voltage line, with a gate electrode receiving the second emission signal.

### CROSS-REFERENCE TO RELATED APPLICATION

The present application claims priority to Korean Patent Application No. 10-2024-0200116, filed on Dec. 30, 2024, the entire contents of which is incorporated herein for all purposes by this reference.

### BACKGROUND

### Technical Field

The present disclosure relates to a pixel and a display device including the pixel.

### Description of the Related Art

With the advancement of the information society, there is an increasing demand for display devices that can show images, and various types of display devices such as liquid crystal display (LCD) devices and organic light emitting diode (OLED) displays are being utilized.

These display devices include several components, including a display panel, a data driver, a gate driver, a timing controller, and a power management unit. The power management unit generates and supplies the various driving voltages required for the operation of these components using the input power.

### BRIEF SUMMARY

The embodiments provide a pixel and a display device including the pixel that are capable of compensating for the threshold voltage of a driving transistor using two scan signals and two emission signals.

The embodiments provide a pixel and a display device including the pixel that are capable of preventing luminance distortion or degradation in display quality caused by changes in the node voltage of the driving transistor due to voltage coupling (parasitic capacitance) during threshold voltage compensation.

The embodiments provide a pixel and a display device including the pixel that are capable of minimizing or eliminating voltage coupling between a compensation capacitor storing the threshold voltage of the driving transistor and the driving transistor.

The embodiments provide a pixel and a display device including the pixel that are capable of preventing an impact on emission luminance by floating one electrode of the compensation capacitor during an emission period.

The embodiments provide a pixel and a display device including the pixel that are capable of allowing a compensation transistor to control the floating of the compensation capacitor, based on an emission signal.

The embodiments provide a pixel and a display device including the pixel that are capable of minimizing current leakage by utilizing an oxide semiconductor thin-film transistor in a hybrid structure.

A pixel according to an embodiment may include a light-emitting element, a driving transistor connected between a high-potential driving voltage line and a first node, with a gate electrode connected to a second node, a switching transistor connected between a data line and the second node, with a gate electrode receiving a first scan signal, an initialization transistor connected between a reference voltage line and the second node, with a gate electrode receiving a second scan signal, a first light-emission transistor connected between the high-potential driving voltage line and the driving transistor, with a gate electrode receiving a first emission signal, a second light-emission transistor connected between the first node and the light-emitting element, with a gate electrode receiving a second emission signal, a first capacitor connected between the first node and the second node, a second capacitor with one electrode connected to the first node, and a compensation transistor connected between the second capacitor and the reference voltage line, with a gate electrode receiving the second emission signal.

Based on the pixel being disposed in an n-th pixel row (where n is a natural number), the second emission transistor may receive an n-th second emission signal through an emission line connected to the n-th pixel row, and the compensation transistor may receive an (n−2)-th second emission signal through an emission line connected to an (n−2)-th pixel row.

Upon the first emission transistor and the second emission transistor being turned on, the compensation transistor may be turned off, causing one electrode of the second capacitor to be floated.

The pixel may further include an anode reset transistor connected between the light-emitting element and a bias voltage line, with a gate electrode receiving the first emission signal.

Some of the driving transistor, the switching transistor, the initialization transistor, the first and the second emission transistors, and the compensation transistor may be oxide thin-film transistors, and the remaining ones may be low temperature poly-silicon (LTPS) thin-film transistors.

The second emission transistor and the compensation transistor may be different types of thin-film transistors.

The second emission transistor may be the LTPS thin-film transistor, and the compensation transistor may be the oxide thin-film transistor.

The pixel may further include a substrate,

a first insulating layer disposed on the substrate, a first semiconductor layer of a first transistor disposed on the first insulating layer, a second insulating layer disposed on the first semiconductor layer, a gate electrode of the first transistor disposed on the second insulating layer, a third insulating layer disposed on the gate electrode of the first transistor, a fourth insulating layer disposed on the third insulating layer, a second semiconductor layer of a second transistor disposed on the fourth insulating layer, a fifth insulating layer disposed on the second semiconductor layer, a gate electrode of the second transistor disposed on the fifth insulating layer, a sixth insulating layer disposed on the gate electrode of the second transistor, and source and drain electrodes of the first transistor and the second transistor disposed on the sixth insulating layer.

The first transistor may be the compensation transistor, and the second transistor may be the second emission transistor.

The first capacitor may include a first electrode disposed on the substrate, a second electrode disposed on the third insulating layer, and a third electrode disposed on the fifth insulating layer.

A display device according to an embodiment may include a display panel including a display area including pixels disposed therein and a non-display area surrounding the display area, a gate driver configured to apply scan signals and emission signals to the pixels, a data driver configured to apply data voltages to the pixels, and a timing controller configured to control the driving timing of the display panel.

Each of the pixels may include a light-emitting element, a driving transistor connected between a high-potential driving voltage line and a first node, with a gate electrode connected to a second node, a switching transistor connected between a data line and the second node, with a gate electrode receiving a first scan signal, an initialization transistor connected between a reference voltage line and the second node, with a gate electrode receiving a second scan signal, a first emission transistor connected between the high-potential driving voltage line and the driving transistor, with a gate electrode receiving a first emission signal, a second emission transistor connected between the first node and the light-emitting element, with a gate electrode receiving a second emission signal, a first capacitor connected between the first node and the second node, a second capacitor with one electrode connected to the first node, and a compensation transistor connected between the second capacitor and the reference voltage line, with a gate electrode receiving the second emission signal.

The gate driver may include shift registers respectively disposed on left and right sides of the display area in the non-display area, and configured in a bilaterally symmetrical form with respect to each other.

The shift registers may include a first shift register configured to output the first scan signal; a second shift register configured to output the second scan signal, a third shift register configured to output the first emission signal, and a fourth shift register configured to output the second emission signal.

The fourth shift register may be configured to output the second emission signal to four adjacent pixel rows.

The fourth shift register may include a plurality of stage circuits connected in a cascade configuration, the plurality of stage circuits including a j-th stage circuit configured to apply the second emission signal to the second emission transistor of pixels disposed in a j-th pixel row and a (j+1)-th pixel row through an emission line extended between the j-th pixel row and the (j+1)-th pixel row.

The j-th stage circuit may apply the second emission signal to the compensation transistor of pixels disposed in a (j+2)-th pixel row and a (j+3)-th pixel row through an emission line extended between the (j+2)-th pixel row and the (j+3)-th pixel row.

Upon the first emission transistor and the second emission transistor being turned on, the compensation transistor may be turned off, causing one electrode of the second capacitor to be floated.

Some of the driving transistor, the switching transistor, the initialization transistor, the first and the second emission transistors, and the compensation transistor may be oxide thin-film transistors, and the remaining ones may be low temperature poly-silicon (LTPS) thin-film transistors.

The second emission transistor and the compensation transistor may be different types of thin-film transistors.

The second emission transistor may be the LTPS thin-film transistor, and the compensation transistor may be the oxide thin-film transistor.

The pixel may further include an anode reset transistor connected between the light-emitting element and a bias voltage line, with a gate electrode receiving the first emission signal.

### BRIEF DESCRIPTION OF THE SEVERAL VIEWS OF THE DRAWINGS

FIG. 1 is a block diagram illustrating the configuration of a display device according to an embodiment;

FIG. 2 is a circuit diagram of a pixel according to an embodiment;

FIG. 3 is a diagram illustrating a driving method of the pixel of FIG. 2 according to an embodiment;

FIG. 4 is a plan view illustrating the configuration of a display panel according to an embodiment;

FIG. 5 is a cross-sectional view illustrating the stacked structure of a display device according to an embodiment;

FIG. 6 is a block diagram illustrating the configuration of a gate driver according to an embodiment;

FIG. 7 is a block diagram illustrating the configuration of a gate driver according to another embodiment; and

FIG. 8 is a diagram illustrating the connection relationship between the fourth shift register of FIG. 6 and a pixel.

### DETAILED DESCRIPTION

Hereinafter, embodiments will be described with reference to accompanying drawings. In the specification, when a component (or area, layer, part, etc.) is mentioned as being “on top of,” “connected to,” or “coupled to” another component, it means that it may be directly connected/coupled to the other component, or a third component may be placed between them.

The same reference numerals refer to the same components. In addition, in the drawings, the thickness, proportions, and dimensions of the components are exaggerated for effective description of the technical content. The expression “and/or” is taken to include one or more combinations that can be defined by associated components.

The terms “first,” “second,” etc., are used to describe various components, but the components should not be limited by these terms. The terms are used only for distinguishing one component from another component. For example, a first component may be referred to as a second component and, similarly, the second component may be referred to as the first component, without departing from the scope of the present disclosure. The singular forms are intended to include the plural forms as well unless the context clearly indicates otherwise.

The terms such as “below,” “lower,” “above,” “upper,” etc., are used to describe the relationship of components depicted in the drawings. The terms are relative concepts and are described based on the direction indicated on the drawing.

It will be further understood that the terms “comprises,” “has,” and the like are intended to specify the presence of stated features, numbers, steps, operations, components, parts, or a combination thereof but are not intended to preclude the presence or possibility of one or more other features, numbers, steps, operations, components, parts, or combinations thereof.

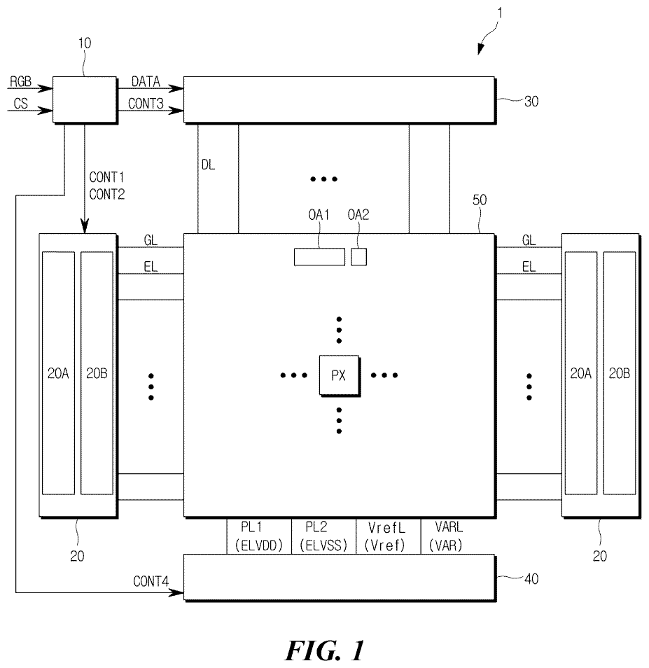

FIG. 1 is a block diagram illustrating a configuration of a display device according to an embodiment.

Referring to FIG. 1, the display device 1 includes a timing controller 10, a gate driver 20, a data driver 30, a power supply 40, and a display panel 50.

The timing controller 10 may receive video signals RGB and control signals CS from external host systems or the like. The video signals may include a plurality of grayscale data. The control signals CS may include a horizontal sync signal, a vertical sync signal, and a main clock signal.

The timing controller 10 processes the video signals RGB and control signals CS to suit the operating conditions of the display panel 50, thereby generating and outputting image data DATA, a gate driving control signal CONT1, an emission driving control signal CONT2, a data driving control signal CONT3, and a power supply control signal CONT4.

The gate driver 20 may include a scan driving circuit 20A that generates scan signals based on the gate drive control signal CONT1 input from the timing controller 10. The scan driving circuit 20A may provide the generated scan signals to the pixels PX through a plurality of scan lines GL. In one embodiment, a single pixel PX may be configured to receive a plurality of scan signals with different waveforms. In this embodiment, the scan driving circuit 20A may provide the plurality of scan signals to the pixels PX of the corresponding pixel rows through the scan lines GL.

The gate driver 20 may further include an emission driving circuit 20B that generates emission control signals based on the emission drive control signal CONT2 input from the timing controller 10. The emission driving circuit 20B may provide the generated emission control signals to the pixels PX of the corresponding pixel rows through emission lines EL.

The gate driver 20 may be configured in a Gate In Panel (GIP) form, implemented on the display panel 50. The gate driver 20 may be disposed on one side of the display panel 50 or, as shown in the drawing, on both sides (e.g., left and right) of the display panel 50. Depending on the driving method, panel design method, etc., the gate driver 20 may be disposed on both sides (e.g., left and right) of the display panel 50, as shown in the drawing, or may be connected to two or more of the four sides of the display panel 50.

The data driver 30 may generate data signals based on the image data DATA and data driving control signal CONT3 output from the timing controller 10. The data driver 30 may provide the generated data signals to the pixels PX through a plurality of data lines DL.

The power supply unit 40 may generate a high-potential driving voltage ELVDD and a low-potential driving voltage ELVSS to be provided to the display panel 50 based on the power supply control signal CONT4. The power supply unit 40 may provide the generated driving voltages ELVDD and ELVSS to the pixels PX through the corresponding voltage lines PL1 and PL2. Additionally, the power supply unit 40 may further generate a reference voltage Vref and/or an anode reset voltage VAR required for driving the pixels PX, and provide the voltages to the pixels PX through the corresponding voltage lines VrefL and VARL.

The display panel 50 includes a plurality of pixels PX (or sub-pixels) arranged thereon. The pixels PX may be arranged, for example, in a matrix form on the display panel 50. The pixels PX arranged in one pixel row are connected to the same scan line GL and emission line EL, and the pixels PX arranged in one pixel column are connected to the same data line DL. The pixels PX may emit light with corresponding luminance in response to the emission control signal applied through the emission line EL, according to the scan signals and data signals supplied through the scan line GL and data line DL.

In one embodiment, each pixel PX may display one of the colors among red, green, or blue. In another embodiment, each pixel PX may display one of the colors among cyan, magenta, or yellow. In various embodiments, each pixel PX may display one of the colors among red, green, blue, or white.

In one embodiment, the display panel 50 may include one or more optical areas OA1 and OA2. The one or more optical areas OA1 and OA2 may be arranged in overlap with one or more optoelectronic devices, such as imaging devices (e.g., cameras or image sensors), proximity sensors, or illuminance sensors.

For the operation of an optoelectronic device, one or more optical areas OA1 and OA2 may include a light-transmissive structure to achieve a transmittance above a certain level. The light-transmissive structure may be formed by patterning the cathode electrode in areas where pixels PX are not arranged. The cathode electrode may be patterned either by laser removal or by selective formation using a cathode deposition prevention layer.

Alternatively, the light-transmissive structure may be formed by separating the light-emitting elements within the pixel PX. In this embodiment, the light-emitting element of the pixel PX is located in the optical areas OA1 and OA2, the plurality of transistors constituting the pixel PX are arranged around the optical areas OA1 and OA2, and the light-emitting element and the transistors may be electrically connected through a transparent metal layer.

The number of pixels PX per unit area in one or more optical areas OA1 and OA2 may be smaller than the number of pixels PX per unit area in the remaining area excluding the optical areas OA1 and OA2. That is, the resolution of the one or more optical areas OA1 and OA2 may be lower than the resolution of the remaining area.

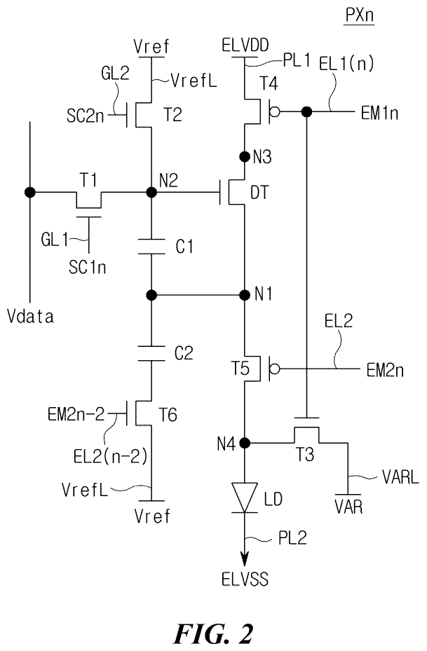

FIG. 2 is a circuit diagram of a pixel according to an embodiment. In the embodiment of FIG. 2, a pixel PXn arranged in the nth pixel row is described as an example.

Referring to FIG. 2, the pixel PXn according to an embodiment may include a control circuit for controlling the amount of driving current to be applied to the light-emitting element LD through the driving transistor DT, which is connected to the driving transistor DT and the light-emitting element LD. For example, the control circuit may include transistors T1 to T6 and capacitors C1 and C2.

The first electrode of the driving transistor DT is configured to receive the high-potential drive voltage ELVDD through the third node N3 and is connected to the high-potential drive voltage line PL1, while the second electrode is connected to the light-emitting element LD through the first node N1. The gate electrode of the driving transistor DT is connected to the second node N2. The driving transistor DT may be turned on based on the voltage applied to the second node N2, thereby controlling the amount of driving current flowing from the high-potential driving voltage ELVDD to the light-emitting element LD.

The first electrode of the first transistor T1 is connected to the data line DL, and the second electrode is connected to the gate electrode of the driving transistor DT through the second node N2. The gate electrode of the second transistor T1 is connected to the first scan line GL1 and may receive the first scan signal SC1n. The first transistor T1 may be turned on according to the first scan signal SC1n applied to the first scan line GL1 and transmit the data voltage Vdata applied to the data line DL to the second node N2. The first transistor T1 may be referred to as a switching transistor.

The first electrode of the second transistor T2 is configured to receive a reference voltage Vref (connected to the reference voltage line VrefL), and the second electrode is connected to the second node N2. The gate electrode of the first transistor T2 is connected to the second scan line GL2 and may receive the second scan signal SC2n. The second transistor T2 may be turned on according to the second scan signal SC2n applied to the second scan line GL2 and transmit the reference voltage Vref to the second node N2. This second transistor T2 may be referred to as an initialization transistor.

The first electrode of the third transistor T3 is configured to receive the anode reset voltage VAR (connected to the anode reset voltage line VARL), and the second electrode is connected to the anode electrode of the light-emitting element LD through the fourth node N4. The gate electrode of the third transistor T3 is connected to the first emission line EL1 to receive the first emission signal EM1n. The third transistor T3 may be turned on according to the first emission signal EM1n applied to the first emission line EL1, thereby transmitting the anode reset voltage VAR to the anode electrode of the light-emitting element LD. This third transistor T3 may be referred to as an anode reset transistor.

The first electrode of the fourth transistor T4 is configured to receive a high-potential driving voltage ELVDD (connected to the high-potential driving voltage line PL1), and the second electrode is connected to the driving transistor DT via the first node N3. The gate electrode of the fourth transistor T4 is connected to the first emission line EL1 and may receive the first emission signal EM1n. In response to the first emission signal EM1n applied to the first emission line EL1, the fourth transistor T4 may connect the high-potential driving voltage line PL1 and the driving transistor DT.

The first electrode of the fifth transistor T5 is connected to the driving transistor DT via the first node N1, and the second electrode is connected to the light-emitting element LD via the fourth node N4. The gate electrode of the fifth transistor T5 is connected to the second emission line EL2 and may receive the second emission signal EM2n. The fifth transistor T5 may connect the driving transistor DT and the light-emitting element LD in response to the second emission signal EM2n applied to the second emission line EL2.

When the fourth transistor T4 and the fifth transistor T5 are turned on, a current path is formed between the high-potential driving voltage ELVDD and the low-potential driving voltage ELVSS, and driving current flows through the light-emitting element LD, causing the light-emitting element LD to emit light. The fourth transistor T4 and the fifth transistor T5 may be referred to as light-emission transistors.

The sixth transistor T6 is connected between the second capacitor C2 and the reference voltage line VrefL. The gate electrode of the sixth transistor T6 may be configured to receive the second emission signal EM2n−2 applied to the fifth transistor T5 of the previous pixel row. For example, the gate electrode of the sixth transistor T6 may be configured to receive the second emission signal EM2n−2 applied to the (n−2)-th pixel row. The sixth transistor T6 may be turned on according to the (n−2)th second emission signal EM2n−2 applied to the second emission line EL2 and may deliver the reference voltage Vref to the second capacitor C2. The sixth transistor T6 may be referred to as a compensation transistor.

The first capacitor C1 is connected between the first node N1 and the second node N2. The first capacitor C1 may store a voltage corresponding to the voltage difference between the first node N1 and the second node N2. For example, the first capacitor C1 may store a voltage corresponding to the voltage difference between the data voltage Vdata applied to the data line DL and the voltage at the first node N1, and maintain the stored voltage throughout a frame period, thereby stabilizing the voltage at the gate electrode of the driving transistor DT (i.e., the second node N2). The first capacitor C1 may be referred to as a storage capacitor.

The second capacitor C2 is connected between the first node N1 and the sixth transistor T6. The second capacitor C2 may store a voltage corresponding to the voltage difference between the first node N1 and the reference voltage Vref when the sixth transistor T6 is turned on. In one embodiment, the second capacitor C2 may store the voltage value of the threshold voltage Vth of the driving transistor DT to compensate for the driving characteristics of the driving transistor DT. For example, the second capacitor C2 may store the voltage value of the threshold voltage Vth of the driving transistor DT during the sampling and programming period when the light-emitting element LD, described later, does not emit light (e.g., while the fifth transistor T5 is turned off). This second capacitor C2 may be referred to as a compensation capacitor.

The light-emitting element LD may have its anode electrode connected to the fourth node N4, and its cathode electrode may be connected to the low-potential drive voltage line PL2 (configured to receive the low-potential drive voltage ELVSS). When the driving transistor DT, the fourth transistor T4, and the fifth transistor T5 are turned on, a current path is formed between the high-potential driving voltage ELVDD and the low-potential driving voltage ELVSS, allowing driving current to flow through the light-emitting element LD. The light-emitting element LD may emit light with brightness corresponding to the amount of applied driving current.

In the embodiment of FIG. 2, the pixel PXn may include an oxide semiconductor thin-film transistor. The oxide semiconductor thin-film transistor includes a gate electrode, a source electrode, and a drain electrode. The oxide semiconductor thin-film transistor has an active layer formed of oxide semiconductor material. Here, the oxide semiconductor may be set as either an amorphous or crystalline oxide semiconductor. The oxide semiconductor thin-film transistor may be configured as an N-type transistor. The oxide semiconductor thin-film transistor may be fabricated using a low-temperature process and has a lower charge mobility compared to the LTPS thin-film transistor. Such an oxide semiconductor thin-film transistor exhibits excellent off-current characteristics.

In an embodiment, the driving transistor DT may be formed as an oxide semiconductor thin-film transistor. At least one of the transistors T2 to T6 may be formed as an oxide semiconductor thin-film transistor.

Furthermore, in one embodiment, the pixel PX may be a hybrid type further including a low temperature poly-silicon (LTPS) thin-film transistor.

The LTPS thin-film transistor includes a gate electrode, a source electrode, and a drain electrode. The LTPS thin-film transistor has an active layer made of polysilicon. The LTPS thin-film transistor may be configured as a P-type thin-film transistor. The LTPS thin-film transistor has a high electron mobility, which provides fast driving characteristics.

In the example of FIG. 2, the fourth transistor T4 and fifth transistor T5 are configured as LTPS thin-film transistors. As the fourth transistor T4 and fifth transistor T5 are configured as LTPS thin-film transistors with fast driving characteristics, when the first emission signal EM1n and second emission signal EM2n are applied at turn-on levels, the fourth transistor T4 and fifth transistor T5 may be turned on quickly, and the emission response speed of the light-emitting element LD may increase.

When the third transistor T3 is an oxide thin-film transistor and the fourth transistor T4 is a LTPS thin-film transistor, the turn-on level of the third transistor T3 is high, and the turn-on level of the fourth transistor T4 is low. Therefore, when the first emission signal EM1n is applied at a high level, the third transistor T3 is turned on, and the fourth transistor T4 is turned off. In contrast, when the first emission signal EM1n is applied at a low level, the third transistor T3 is turned off, and the fourth transistor T4 is turned on. Thus, the third transistor T3 and fourth transistor T4 may be configured to alternate between turning on and turning off.

However, this embodiment is not limited thereto. That is, in various other embodiments, except for the third transistor T3, at least one of the driving transistor DT and other transistors T1, T2, and T6 may be further configured as an LTPS thin-film transistor.

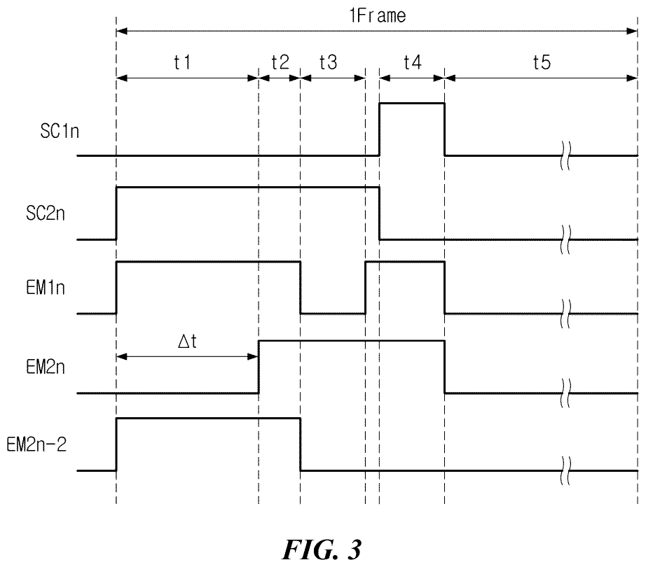

FIG. 3 is a diagram illustrating a driving method of the pixel of FIG. 2 according to an embodiment.

Referring to FIGS. 2 and 3 together, one frame 1Frame may include an initialization period t1, sampling periods t2 and t3, a programming period t4, and an emission period t5.

During the initialization period t1, the second scan signal SC2n at the turn-on level is applied, causing the second transistor T2 to turn on. Additionally, during the initialization period t1, the first emission signal EM1n at the high level and the second emission signal EM2n at the low level are applied, causing the third transistor T3 and the fifth transistor T5 to turn on.

When the reference voltage Vref is applied to the second node N2 through the turned-on second transistor T2, the gate electrode of the driving transistor DT may be initialized to the reference voltage Vref. The reference voltage Vref may be a positive voltage and may correspond to the voltage for black luminance, but is not limited thereto.

When the anode reset voltage VAR is applied to the fourth node N4 through the turned-on third transistor T3, the anode electrode of the light-emitting element LD may be initialized to the anode reset voltage VAR. The anode reset voltage VAR is further applied to the first node N1 through the turned-on fifth transistor T5. The anode reset voltage VAR may be the same as or different from the reference voltage Vref. For example, the anode reset voltage VAR may be a voltage lower than the reference voltage Vref or a negative voltage, but is not limited thereto.

The first capacitor C1 stores a voltage corresponding to the voltage difference between the second node N2 and the first node N1. That is, during the first initialization period t1, the first capacitor C1 may store a voltage Vref-VAR corresponding to the difference between the reference voltage Vref and the anode reset voltage VAR.

During the initialization period t1, the high-level (n−2)-th second emission signal EM2n−2 may also be applied, causing the sixth transistor T6 to be turned on. Through the turned-on sixth transistor T6, the reference voltage Vref may be applied to the second capacitor C2. The second capacitor C2 may store a voltage Vref-VAR corresponding to the voltage difference between the reference voltage Vref and the first node N1.

During the initialization period t1, the first node N1 is coupled to the reference voltage line VrefL through the second capacitor C2, but since the anode initialization voltage VAR is applied to the first node N1 through the turned-on fifth transistor T5, the voltage is stably maintained.

During the first sampling period t2, the second emission signal EM2n first transitions to a high level, causing the fifth transistor T5 to be turned off. In this case, the voltage at the first node N1 is maintained at the previously set voltage by the first capacitor C1 and the second capacitor C2.

During the second sampling period t3, the first emission signal EM1n transitions to a low level, turning off the third transistor T3 and turning on the fourth transistor T4. Then, the (n−2)-th second emission signal EM2n−2 transitions to a low level, turning off the sixth transistor T6.

When the high-potential drive voltage ELVDD is applied to the third node N3 through the turned-on fourth transistor T4, the high-potential drive voltage ELVDD may be applied to the drain electrode of the driving transistor DT. The reference voltage Vref is applied to the gate electrode of the driving transistor DT through the second transistor T2. The source electrode of the driving transistor DT becomes a voltage-variable state.

As a result, during the second sampling period t3, the driving transistor DT may be turned on and operate in a source follower mode. That is, the driving transistor DT may supply drain-source current to the first node N1 until the gate-source voltage reaches the threshold voltage Vth. The voltage at the first node N1 gradually increases from the previously set voltage VAR and may converge to the voltage Vref-Vth, which corresponds to the difference between the reference voltage Vref and the threshold voltage Vth.

After the driving transistor DT becomes saturated, the first capacitor C1 stores the threshold voltage Vth corresponding to the voltage difference between the second node N2 and the first node N1. The second capacitor C2 stores the threshold voltage Vth corresponding to the voltage difference between the first node N1 and the reference voltage Vref.

During the programming period t4, the second scan signal SC2n may transition to the turn-off level, and the first emission signal EM1n may transition to a high level. As a result, the second transistor T2 and the fourth transistor T4 may be turned off, while the third transistor T3 may be turned on. Additionally, during the programming period t4, the first scan signal SC1n may be applied at the turn-on level, turning on the first transistor T1.

When the data voltage Vdata is applied to the second node N2 through the turned-on first transistor T1, the data voltage Vdata may be applied to the gate electrode of the driving transistor DT. The voltage at the gate node of the driving transistor DT may rise to the voltage corresponding to the data voltage Vdata.

During the programming period t4, the voltage at the first node N1 may be maintained at the threshold voltage Vth by the second capacitor C2.

The first capacitor C1 stores the voltage corresponding to the voltage difference between the second node N2 and the first node N1. That is, during the programming period t3, the first capacitor C1 may store the voltage corresponding to the difference between the data voltage Vdata and the threshold voltage Vth (Vdata-Vth).

During the emission period t5, the first scan signal SC1n may transition to the turn-off level, causing the first transistor T1 to be turned off. Additionally, during the emission period t5, the (n−2)-th second emission signal EM2n−2 may be maintained to a low level, causing the sixth transistor T6 to be turned off, and one electrode of the second capacitor C2 may be maintained in floating state.

During the emission period t5, when the first emission signal EM1n and the second emission signal EM2n transition to low levels, the third transistor T3 may be turned off, and the fourth and fifth transistors T4 and T5 may be turned on.

Through the turned-on fourth and fifth transistors T4 and T5, a current path may be formed from the high-potential drive voltage ELVDD through the driving transistor DT to the light-emitting element LD. As a result, the driving current corresponding to the programmed voltage in the driving transistor DT is provided to the light-emitting element LD to emit light at the corresponding brightness.

Here, the programmed voltage in the driving transistor DT is the voltage programmed in the first capacitor C1, which is the data voltage Vdata compensated by the threshold voltage Vth. Therefore, the degradation of the driving transistor DT may be compensated.

In the embodiments illustrated in FIGS. 2 and 3, the fifth transistor T5 and the sixth transistor T6 are configured to receive the emission signals EM2n−2 and EM2n, which are the same waveform with a phase shift by a predetermined period Δt. For example, the n-th second emission signal EM2n may have a waveform that is phase-shifted by 1/m compared to the n−2-th second emission signal EM2n−2. Here, m is the number of phases of the total emission signals generated through the emission drive circuit 20B.

When the sixth transistor T6 transitions from the off state to the on state and applies the reference voltage Vref to the second capacitor C2, the fifth transistor T5 may be turned on and apply the anode reset voltage VAR to the first node N1. That is, when the sixth transistor T6 is turned on, the voltage at the first node N1 may be prevented from rising due to the coupling with the second capacitor C2. In this embodiment, before the threshold voltage Vth of the driving transistor DT is sampled during the second sampling period t3, the voltage at the first node N1 may be stably maintained, allowing for accurate threshold voltage Vth compensation.

Meanwhile, during the emission period t5, when the fifth transistor T5 is turned on, the voltage at the first node N1 may change rapidly. When a second capacitor C2 with a large electrical capacitance is electrically connected to the respective nodes, voltage coupling may occur between the first node N1 and the second capacitor C2. This may interfere with the voltage fluctuation at the first node N1, and delay may occur until the light-emitting element LD emits with the desired luminance. Furthermore, when the voltage at the first node N1 fluctuates due to voltage coupling, distortion may occur in the voltage of the second node N2, which is indirectly connected to the first node N1, causing the source-gate voltage of the driving transistor DT to fail to be maintained stably.

In the embodiment described above, during the emission period t5, when the fifth transistor T5 is turned on, the sixth transistor T6 is turned off, thereby floating one end of the second capacitor C2. As a result, the second capacitor C2, in addition to holding the threshold voltage Vth during the sampling and programming periods t3 and t4, does not participate in the voltage of the emission nodes, the first node N1 and the fourth node N4, during the emission period t5. That is, during the emission period t5, voltage coupling between the second capacitor C2 and the first node N1 may be removed or minimized. Therefore, emission delay, luminance distortion, or degradation in display quality caused by voltage coupling during the emission period t5 may be prevented.

Additionally, in the aforementioned embodiment, the second capacitor C2 is supplied with the reference voltage Vref through the sixth transistor T6. That is, during the compensation operation of the second capacitor C2, the voltage at one electrode of the second capacitor C2 may be fixed to a DC voltage and stabilized through the sixth transistor T6. Furthermore, since a separate circuit element (for example, a transistor) and signal wiring for supplying the voltage to the second capacitor C2 are not required, the size and complexity of the circuit are reduced, and power consumption may be decreased.

In the embodiments of FIGS. 2 and 3, the pixel PX is driven using two scan signals Sc1n and SC2n and two emission signals EM1n and EM2n. As the number of scan signals SC1n and SC2n and emission signals Em1n and EM2n decreases, the design of the gate driver 20 (FIG. 1) becomes easier, and the size and circuit complexity are reduced, leading to a decrease in the size and manufacturing cost of the display device 1 (FIG. 1). In the embodiments of FIGS. 2 and 3, even with the use of only two scan signals SC1n and SC2n to compensate for the threshold voltage of the driving transistor DT, since the one electrode of the second capacitor C2 can be controlled to a floating state during the emission period t5, the gate driver 20 and the display device 1 can be miniaturized and thinned, and design flexibility can be improved.

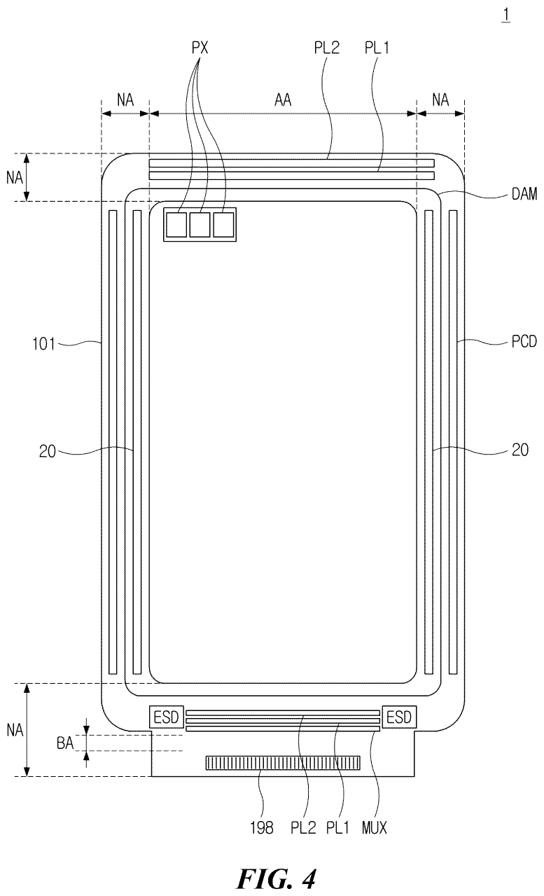

FIG. 4 is a plan view illustrating the configuration of a display panel according to an embodiment.

Referring to FIG. 4, the display device 1 may include driving circuits for generating various signals or driving a plurality of pixels PX in the display area AA. Some of the driving circuits may be included on the display panel 50. The driving circuits for controlling (or driving) the pixels PX may include a gate driver 20, data lines, a multiplexer MUX, an electrostatic discharge circuit ESD, a high-potential driving voltage line PL1, a low-potential driving voltage line PL2, and an inverter circuit.

The display device 1 may further include additional elements for driving the pixels PX. These additional elements may include circuits for providing functions such as touch detection, user authentication (e.g., fingerprint recognition), multi-level pressure detection, and tactile feedback. The additional elements may be arranged in the non-display area NA or in an external circuit connected to the non-display area NA through connection wiring.

The display panel 50 may include a substrate 101, and the substrate 101 may include a display area (active area, AA) and a non-display area (non-active area, NA). The display area AA of the substrate 101 may be the area where a plurality of pixels PX are arranged and images are displayed. The non-display area NA of the substrate 101 may be the area where images are not displayed. For example, the non-display area NA may be the bezel area, but is not limited to this term. The non-display area NA may be adjacent to the display area AA and placed outward of the display area AA. Alternatively, the non-display area NA may be arranged to surround the entire or part of the display area AA. Additionally, the non-display area NA may also be the area where a plurality of pixels PX are not arranged, but it is not limited to this.

In FIG. 4, the non-display area NA is shown surrounding the rectangular display area AA; however, the shape and arrangement of the display area AA and the adjacent non-display area NA are not limited to the illustration. The display area AA and non-display area NA may have shapes suitable for the design of an electronic device equipped with the display device 1. In the case of display devices for wearable devices, such as wristwatches, the display area AA and non-display area NA may have a circular shape, and the concepts of these embodiments may also be applied to free-form display devices, such as those used in vehicle dashboards. Exemplary shapes of the display area AA may include a pentagon, hexagon, octagon, circle, ellipse, or the like, but are not limited thereto.

A bending area BA may be provided in a portion of the non-display area NA. The bending area BA may be located between the pad portion 198 in the non-display area NA and the display area AA. Additionally, the bending area BA may be the area where the connection wiring is formed.

The bending area BA may be a region where a portion of the substrate 101 is bent to place the pad portion 198 and an external module bonded to the pad portion 198 on the back side of the substrate 101. For example, as the bending area BA is bent toward the back side of the substrate 101, the external module bonded to the pad portion 198 may move to the back side of the substrate 101, and the external module may not be visible when viewed from the top of the substrate 101. Furthermore, as the bending area BA is bent, the size of the non-display area NA visible from the top of the substrate 101 may decrease, enabling the implementation of a narrow bezel. In FIG. 4, the non-display area NA is shown to have a bending area BA, but this is not limited to the illustration. For example, the bending area BA may be located in the display area AA, and since the display area AA itself may be bent in various directions, the bending area BA located in the display area AA may also have the effects mentioned in the present disclosure.

A pad portion 198 is disposed on one side of the non-display area NA. The pad portion 198 is a metal pattern to which external modules, such as a flexible printed circuit board (FPCB) or chip-on-film (COF), are bonded. Although the pad portion 198 is shown to be disposed on one side of the substrate 101, the form and placement of the pad portion 198 are not limited thereto.

A gate driver 20, which provides gate signals to the thin-film transistors, may be disposed on the other side of the non-display area NA. The gate driver 20 includes various gate driving circuits, which may be directly formed on the substrate 101. In this case, the gate driver 20 may be a gate-in-panel (GIP).

The gate driver 20 may be disposed between a dam DAM in the non-display area NA and the display area AA of the substrate 101.

The high-potential driving voltage line PL1, low-potential driving voltage line PL2, multiplexer MUX, electrostatic discharge circuit ESD, and a plurality of connection wiring portions may be arranged between the display area AA and the pad portion 198 in the non-display area NA.

The high-potential driving voltage line PL1, low-potential driving voltage line PL2, multiplexer MUX, and electrostatic discharge circuit ESD may be arranged between the display area AA and the bending area BA.

The connection wiring portions may be arranged in the non-display area NA. For example, the connection wiring portions may be arranged in the bending area BA of the non-display area NA, where the substrate is bent. The connection wiring portion may be configured to deliver signals (voltages) from an external module bonded to the pad portion 198 to a circuit portion such as the display area AA or the gate driver 20. For example, various signals, such as signals for driving the gate driver 20, data signals, high-potential driving voltage, and low-potential driving voltage, may be transmitted through the connection wiring portion.

A dam DAM may be arranged in the non-display area NA to surround all or part of the display area AA. The dam DAM may be adjacent to the display area AA and disposed outward of the display area AA.

The dam DAM may be arranged along the periphery of the display area AA to control the flow of an organic layer, which is the material of the second encapsulation layer in the encapsulation layer to be described later, disposed on the light-emitting element layer. The number of dams DAM may be configured as one or more.

The dam DAM may be arranged between the display area AA and the high-potential driving voltage line PL1, low-potential driving voltage line PL2, multiplexer MUX, or electrostatic discharge circuit ESD.

A panel crack detector (PCD) may further be arranged in a portion of the non-display area NA of the substrate 101.

The panel crack detector PCD may be arranged between the edge (or end) of the substrate 101 and the dam DAM. Alternatively, the panel crack detector PCD may be arranged below the dam DAM and at least partially overlap with the dam DAM.

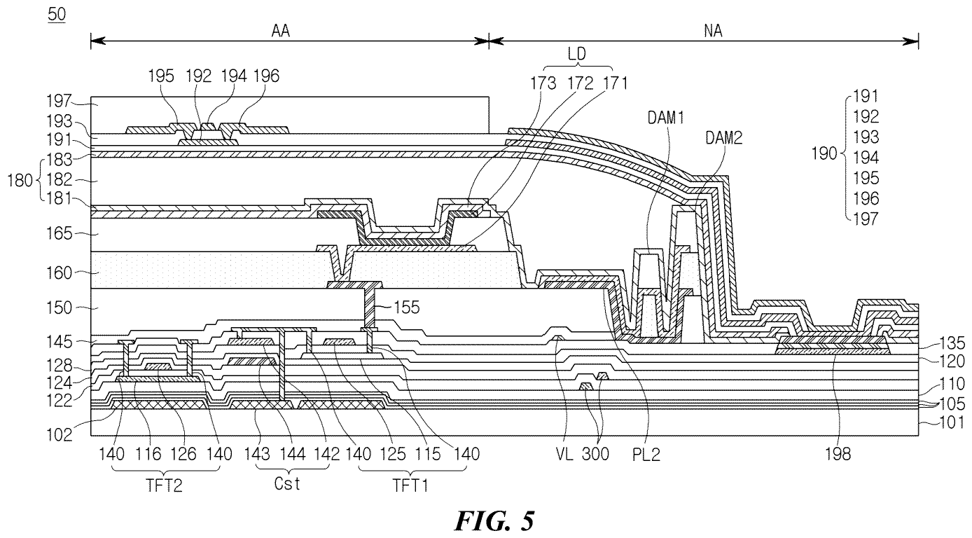

FIG. 5 is a cross-sectional view illustrating the stacked structure of a display device according to an embodiment.

Referring to FIG. 5, the display panel 50 includes a display area AA, where pixels PX are located, and a non-display area NA, which is arranged to surround the display area AA and accommodates the gate driver 20 (FIG. 1) and the data driver 30 (FIG. 1). The display panel 50 may include a substrate 101, thin-film transistors TFT1 and TFT2, a bank layer 165, a light-emitting element LD, an encapsulation layer 180, a touch layer 190, a touch protection film 197, dams DAM1 and DAM2, and a pad portion 198.

The substrate 101 supports various components of the display panel 50. The substrate 101 may be formed of a transparent dielectric material such as glass, plastic, and the like. In the case of being made of plastic, the substrate 101 may be referred to as a plastic film or a plastic substrate. For example, the substrate 101 may be in the form of a film and include one of a polyimide-based polymer, a polyester-based polymer, a silicone-based polymer, an acrylic-based polymer, a polyolefin-based polymer, and their copolymers, but the embodiments of this specification are not limited to thereto. Additionally, when made of plastic, the substrate 101 may be formed in a double structure. For example, the substrate may be a double structure with an adhesive layer between the first polyimide layer and the second polyimide layer.

When made of glass, the substrate 101 may be referred to as a glass substrate. For example, the glass substrate may include a shielding metal 102 beneath the thin-film transistors TFT1 and TFT2, serving to protect against external light or signal interference.

In the display area AA, thin-film transistors TFT1 and TFT2 for driving the light-emitting element LD may be arranged on the substrate 101. The thin-film transistors TFT1 and TFT2 drive the light-emitting element LD in the display area AA.

For convenience of explanation, FIG. 5 shows only the driving transistor TFT1 (e.g., driving transistor DT in FIG. 2) and one switching transistor TFT2 (e.g., light-emission transistor T4 and T5 in FIG. 2) that may be included in the display device 1, but the thin-film transistors TFT1 and TFT2 are not limited to this configuration. Hereinafter, an example in which the thin-film transistors TFT1 and TFT2 have a coplanar structure will be described, but the thin-film transistors TFT1 and TFT2 may also be implemented in other various structures, such as a staggered structure.

The second thin-film transistor TFT2 may include a semiconductor layer 116, a gate electrode 126, and source and drain electrodes 140. The semiconductor layer 116 may be made of polysilicon (p-Si), and in this case, a certain region may be doped with impurities. Additionally, the semiconductor layer 116 may be composed of amorphous silicon (a-Si) or various organic semiconductor materials such as pentacene. The semiconductor layer 116 may be made of oxide. The embodiments of the present specification are not limited to the material constituting the semiconductor layer 116. The semiconductor layer 116 may be an active layer, but the term is not limited thereto.

The gate electrode 126 may be arranged on top of the semiconductor layer 116. The gate electrode 126 may be made of various conductive materials, such as magnesium (Mg), aluminum (Al), nickel (Ni), chromium (Cr), molybdenum (Mo), tungsten (W), gold (Au), or their alloys, but the embodiments of this specification are not limited thereto.

The gate insulating layer 122 may be arranged between the semiconductor layer 116 and the gate electrode 126. The gate insulating layer 122 may be a layer for insulating the semiconductor layer 116 and the gate electrode 126 and may be made of an insulating material. For example, the gate insulating layer 122 may be composed of a single layer or multilayer of silicon oxide (SiOx) or silicon nitride (SiNx), but is not limited thereto.

The source and drain electrodes 140 are electrically connected to the semiconductor layer 116 and spaced apart from each other, and may be made of a conductive material such as copper (Cu), aluminum (Al), molybdenum (Mo), titanium (Ti), or their alloys, but are not limited thereto.

A buffer layer 105, shielding metal 102, and first insulating layer 110 may be arranged between the semiconductor layer 116 and the substrate 101. The buffer layer 105 may delay the diffusion of moisture and/or oxygen that has penetrated the substrate 101. The first insulating layer 110 protects the semiconductor layer 115 and may block various types of defects entering from the substrate 101. The shielding metal 102 is arranged between the buffer layer 105 and the first insulating layer 110 to protect the second thin-film transistor TFT2 from external light or signal interference.

The topmost layer of the buffer layer 105 in contact with the first insulating layer 110 may be formed of a material with different etching characteristics compared to the other layers of the buffer layer 105, the first insulating layer 110, the second insulating layer 120, and the third insulating layer 135. The topmost layer of the buffer layer 105 in contact with the first insulating layer 110 may be formed of either silicon nitride (SiNx) or silicon oxide (SiOx). The other layers of the buffer layer 105, the first insulating layer 110, the second insulating layer 120, and the third insulating layer 135 may be formed of the remaining material, either silicon nitride (SiNx) or silicon oxide (SiOx). For example, the topmost layer of the buffer layer 105 in contact with the first insulating layer 110 may be formed of silicon nitride (SiNx), and the other layers of the buffer layer 105, the first insulating layer 110, the second insulating layer 120, and the third insulating layer 135 may be formed of silicon oxide (SiOx), but they are not limited thereto.

The first thin-film transistor TFT1 may include a semiconductor layer 115, a gate electrode 125, and source and drain electrodes 140. A second insulating layer 120 (gate insulating layer) may be arranged between the semiconductor layer 115 and the gate electrode 125.

The interlayer insulating layer 128 may be arranged between the first thin-film transistor TFT1 and the second thin-film transistor TFT2.

The first thin-film transistor TFT1 may include a semiconductor layer 115 arranged on the interlayer insulating layer 128, a gate electrode 125 overlapping the semiconductor layer 115 through the second insulating layer 120, and source and drain electrodes 140 formed on the third insulating layer 135 and in contact with the semiconductor layer 115.

The semiconductor layer 115 may be the region where a channel is formed when driving the first thin-film transistor TFT2. The semiconductor layer 115 may be formed of an oxide semiconductor, and may also be formed of amorphous silicon (a-Si), polycrystalline silicon (poly-Si), or various organic semiconductors such as pentacene, but is not limited to these materials. The semiconductor layer 115 may be formed on the interlayer insulating layer 128. The semiconductor layer 115 may include a channel region, a source region, and a drain region. The channel region may be formed by overlapping the gate electrode 125 with the channel region of the semiconductor layer 115 through the second insulating layer 120, thereby forming a channel between the source and drain regions. The source region may be electrically connected to the source electrode 140 through a contact hole that penetrates the second insulating layer 120 and the third insulating layer 135. The drain region may be electrically connected to the drain electrode 140 through a contact hole that penetrates the second insulating layer 120 and the third insulating layer 135.

The gate electrode 125 may be formed on the second insulating layer 120 and may overlap the channel region of the semiconductor layer 115 through the second insulating layer 120. The gate electrode 125 may be formed of a first conductive material, which is a single layer or multilayer of one of magnesium (Mg), molybdenum (Mo), aluminum (Al), chromium (Cr), gold (Au), titanium (Ti), nickel (Ni), neodymium (Nd), or copper (Cu), or their alloys, but is not limited to these materials.

The source electrode 140 may be connected to the exposed source region of the semiconductor layer 115 through a contact hole that penetrates the second insulating layer 120 and the third insulating layer 135. The drain electrode 140 may face the source electrode 140 and may be connected to the drain region of the semiconductor layer 115 through a contact hole that penetrates the second insulating layer 120 and the third insulating layer 135. These source and drain electrodes 140 may be formed of a second conductive material, which is a single layer or multilayer of one or more of molybdenum (Mo), aluminum (Al), chromium (Cr), gold (Au), titanium (Ti), nickel (Ni), neodymium (Nd), or copper (Cu), or their alloys, but is not limited to these materials.

A capacitor Cst may be further disposed on the substrate 101. The capacitor Cst may be a storage capacitor C1 (FIG. 2) or a compensation capacitor C2 (FIG. 2). For convenience of explanation, FIG. 5 illustrates the storage capacitor C1 as an example. The capacitor Cst may be configured to include a first electrode 143, a second electrode 144, and a third electrode 142.

At least one insulating layer may be disposed between the first electrode 143 and the second electrode 144, and at least one insulating layer may be disposed between the second electrode 144 and the third electrode 142. At least one of the first electrode 143, the second electrode 144, and the third electrode 142 may be connected to the source electrode 140 or drain electrode 140 of the thin-film transistors TFT1 or TFT2.

A connection electrode 155 may be disposed between the first intermediate layer 150 and the second intermediate layer 160. The connection electrode 155 may be connected to the drain electrode 140 through a connection electrode contact hole passing through the protective layer 145 and the first intermediate layer 150. The connection electrode 155 may be made of a material with low resistivity, similar or identical to the drain electrode 140, but is not limited thereto.

A light-emitting element LD including a light-emitting layer 172 may be disposed on the second intermediate layer 160 and the bank layer 165. The light-emitting element LD may include an anode electrode 171, at least one light-emitting layer 172 formed on the anode electrode 171, and a cathode electrode 173 formed on the light-emitting layer 172.

The anode electrode 171 may be disposed on the first intermediate layer 150 through a contact hole passing through the second intermediate layer 160 and may be electrically connected to the connection electrode 155 exposed on the upper surface of the second intermediate layer 160.

The anode electrode 171 of each pixel may be formed to be exposed by the bank layer 165. The bank layer 165 may be formed of an opaque material (e.g., black) to prevent light interference between adjacent pixels. In this case, the bank layer 165 may include a light-blocking material made of at least one of colorant, organic black, or carbon, but is not limited to these.

At least one light-emitting layer 172 may be formed on the anode electrode 171 in the light-emitting region defined by the bank layer 165. At least one light-emitting layer 172 may be disposed on the anode electrode 171 and include a hole transport layer, a hole injection layer, a hole blocking layer, the light-emitting layer 172, an electron injection layer, an electron blocking layer, and an electron transport layer that are be sequentially or reversely stacked depending on the emission direction. Additionally, the light-emitting layer 172 may have a first and a second light-emitting stack facing each other with a charge generation layer therebetween. In this case, one of the light-emitting layers 172 in the first or second light-emitting stacks may generate blue light, and the remaining light-emitting layer 172 may generate yellow-green light, such that white light is generated through the first and second light-emitting stacks. The white light generated in the light-emitting stack may be incident on a color filter located above or below the light-emitting layer 172, allowing for the implementation of color images. Alternatively, without a separate color filter, color light corresponding to each pixel may be generated from each light-emitting layer 172 to implement color images. For example, the light-emitting layer 172 of a red pixel may generate red light, the light-emitting layer 172 of a green pixel may generate green light, and the light-emitting layer 172 of a blue pixel may generate blue light.

The cathode electrode 173 may be formed to face the anode electrode 171 with the light-emitting layer 172 in between and may receive a low-potential drive voltage ELVSS.

The encapsulation layer 180 may block external moisture or oxygen from penetrating, protecting the light-emitting element LD, which is vulnerable to external moisture or oxygen. To achieve this, the encapsulation layer 180 may include at least one inorganic encapsulation layer and at least one organic encapsulation layer, but this is not limited thereto. Hereinafter, the structure of the encapsulation layer 180, where the first encapsulation layer 181, the second encapsulation layer 182, and the third encapsulation layer 183 are sequentially stacked, will be explained as an example.

The first encapsulation layer 181 is formed on the substrate 101 where the cathode electrode 173 is formed. The third encapsulation layer 183 is formed on the substrate 101 where the second encapsulation layer 182 is formed, and may be configured, along with the first encapsulation layer 181, to surround the top surface, bottom surface, and side surfaces of the second encapsulation layer 182. The first encapsulation layer 181 and the third encapsulation layer 183 may minimize or prevent the penetration of external moisture or oxygen into the light-emitting element LD. The first encapsulation layer 181 and the third encapsulation layer 183 may be formed of inorganic insulating materials, such as silicon nitride (SiNx), silicon oxide (SiOx), silicon oxynitride (SiON), or aluminum oxide (Al2O3), which may be deposited at low temperatures. Since the first encapsulation layer 181 and the third encapsulation layer 183 are deposited in a low-temperature atmosphere, they may prevent damage to the light-emitting element LD, which is vulnerable to high temperatures during the deposition process of the first and third encapsulation layers 181 and 183.

The second encapsulation layer 182 may serve as a buffer to alleviate stress between layers due to the bending of the display device 1 (FIG. 1), and may flatten the step differences between the layers. The second encapsulation layer 182 may be formed on the substrate 101, where the first encapsulation layer 181 is formed, using non-photosensitive organic insulating materials such as acrylic resin, epoxy resin, phenolic resin, polyamide resin, polyimide resin, polyethylene, or silicon oxycarbide (SiOC), or photosensitive organic insulating materials such as photoacrylic, but is not limited to these materials. When the second encapsulation layer 182 is formed by an inkjet method, dams DAM1 and DAM2 may be placed to prevent the liquid form of the second encapsulation layer 182 from diffusing to the edge of the substrate 101. The dams DAM1 and DAM2 may be placed closer to the edge of the substrate 101 than the second encapsulation layer 182. Through these dams DAM1 and DAM2, diffusion of the second encapsulation layer 182 into the pad area, where the conductive pads are placed at the outermost edge of the substrate 101, may be prevented.

The dams DAM1 and DAM2 are designed to prevent the diffusion of the second encapsulation layer 182. However, if the second encapsulation layer 182 exceeds the height of the dams DAM1 and DAM2 during the process, the organic material of the second encapsulation layer 182 may be exposed to the outside, allowing moisture or other elements to easily penetrate into the light-emitting element. Therefore, to prevent this, the dams DAM1 and DAM2 may be formed with at least two layers. The dams DAM1 and DAM2 may be provided in two or more layers. In this case, the two or more dams DAM1 and DAM2 may be formed with the same or different structures.

The dams DAM1 and DAM2 may be placed on a second interlayer insulating layer disposed on the third insulating layer 135 in the non-display area NA. The embodiments in this specification are not limited to this, and the second interlayer insulating layer may be the third insulating layer 135.

The first dam DAM1 may be formed simultaneously with the second intermediate layer 160 and the bank layer 165. When the second intermediate layer 160 is formed, the lower layer of the first dam DAM1 is formed together, and when the bank layer 165 is formed, the upper layer of the first dam DAM1 is formed together, resulting in a double-layer structure that is stacked and formed.

In the first dam DAM1, a metal layer of the same material as the anode electrode 171 may be placed between the upper and lower layers, and below the lower layer, a metal layer of the same material as the source and drain electrodes 140 of the thin-film transistors TFT1 and TFT2 and a metal layer of the same material as the connection electrode 155 may be arranged in contact with each other.

The second dam DAM2 may be formed simultaneously with the first intermediate layer 150, the second intermediate layer 160, and the bank layer 165. When the first intermediate layer 150 is formed, the lower layer of the second dam DAM2 is formed together, when the second intermediate layer 160 is formed, the middle layer of the second dam DAM2 is formed together, and when the bank layer 165 is formed, the upper layer of the second dam DAM2 is formed together, resulting in a triple-layer stacked structure.

In the second dam DAM2, a metal layer of the same material as the anode electrode 171 may be placed between the upper and middle layers, a metal layer of the same material as the connection electrode 155 may be placed between the middle and lower layers, and a metal layer of the same material as the source and drain electrodes 140 of the thin-film transistors TFT1 and TFT2 may be placed below the lower layer.

Therefore, the dams DAM1 and DAM2 may be composed of the same material as the first intermediate layer 150, the second intermediate layer 160, and the bank layer 165, but are not limited thereto. Additionally, there may be at least one insulating layer, including a second interlayer insulating layer, arranged below the first intermediate layer 150.

The dams DAM1 and DAM2 may be formed overlapping with the low-potential driving voltage line PL2. For example, in the non-display area NA, the dams DAM1 and DAM2 may have the low-potential driving voltage line PL2 formed in the lower layers of the region where they are located.

The low-potential driving voltage line PL2 and the gate driver 20 configured in a GIP (Gate In Panel) form are formed around the outer edges of the display panel, with the low-potential driving voltage line PL2 being positioned outside the gate driver 20. This low-potential driving voltage line PL2 may be connected to the cathode electrode 173 and may serve as the low-potential driving voltage ELVSS, as shown in FIG. 1.

The low-potential driving voltage line PL2 may be placed on the same layer as the connection electrode 155 on the first intermediate layer 150. Alternatively, the low-potential driving voltage line PL2 may be placed on the same layer as the source and drain electrodes 140 of the thin-film transistor TFT on the third insulating layer 135, or placed on the same layer as the gate electrode 125 of the thin-film transistor TFT1 on the second insulating layer 120. However, the embodiments are not limited to these configurations.

At least one power line VL may be placed between the gate driver 20 and the display area AA. At least one power line VL may be placed on the same layer as the source and drain electrodes 140 of the thin-film transistor TFT. Of course, it is not limited thereto. Although it is simply expressed in the drawing, at least one power line VL, consisting of the anode reset voltage line VARL (FIG. 1) and the reference voltage line VrefL, may be arranged side by side in the same layer. Alternatively, the anode reset voltage line VARL (FIG. 1) and the reference voltage line VrefL may be arranged side by side or overlapping in different layers. At least one power line VL is shown as being placed between the gate driver 20 and the display area AA, but the embodiments are not limited thereto.

On the encapsulation layer 180, a touch layer 190 may be placed. The touch buffer layer 191 in the touch layer 190 may be positioned between the touch sensor metal, which includes the touch electrode connection lines 192, 194 and the touch electrodes 195, 196, and the cathode electrode 173 of the light-emitting element LD.

The touch buffer layer 191 may prevent chemicals (such as developer or etchant) used in the manufacturing process of the touch sensor metal disposed on the touch buffer layer 191, or moisture from the outside, from penetrating into the light-emitting layer 172, which contains organic material. As a result, the touch buffer layer 191 may prevent damage to the light-emitting layer 172, which is vulnerable to chemicals or moisture.

The touch buffer layer 191 is formed from an organic insulating material having a low dielectric constant of 1-3, and may be formed at a low temperature (e.g., below 100° C.) to prevent damage to the light-emitting layer 172, which contains organic material and is sensitive to high temperatures. For example, the touch buffer layer 191 may be made of acrylic-based, epoxy-based, or siloxane-based materials. The touch buffer layer 191, which has flattening performance with an organic insulating material, may prevent damage to the encapsulation layer 180 due to the bending of the organic light-emitting display device and the breaking of the touch sensor metal formed on the touch buffer layer 191.

According to a mutual-capacitance-based touch sensor structure, the touch electrodes 195 and 196 are arranged on the touch buffer layer 191, and the touch electrodes 195 and 196 may be arranged to cross each other.

The touch electrode connection lines 192 and 194 may electrically connect the touch electrodes 195 and 196. The touch electrode connection lines 192 and 194 and the touch electrodes 195 and 196 may be positioned in different layers, separated by the touch insulating layer 193.

The touch electrode connection lines 192 and 194 are arranged to overlap the bank layer 165, which can prevent a reduction in aperture ratio.

Meanwhile, the touch electrodes 195 and 196 may be electrically connected to the touch driving circuit (not shown) through the pad portion 198, with part of the touch electrode connection line 192 passing through the upper and side portions of the encapsulation layer 180 and the upper and side portions of the dam DAM1 and DAM2.

Part of the touch electrode connection line 192 may receive a touch drive signal from the touch driving circuit and deliver it to the touch electrodes 195 and 196, while also transmitting the touch sensing signals from the touch electrodes 195 and 196 to the touch driving circuit.

The touch electrode connection line 192 may be composed of double wiring, with each layer of the touch electrode connection line 192 being formed on the touch buffer layer 191 and the touch insulating layer 193, respectively.

A touch protective layer 197 may be disposed on the touch electrodes 195 and 196. Although the touch protective layer 197 is shown in the drawing as being disposed only on the touch electrodes 195 and 196, this is not limited to that, and the touch protective layer 197 may extend to before or after the dam DAM1 and DAM2, and may also be disposed on the touch electrode connection lines 192 and 194.

The pad portion 198 may be configured to include a first pad layer made of the same material as the gate electrode 126, a second pad layer made of the same material as the source and drain electrodes 140, and a third pad layer made of the same material as the touch electrodes 195 and 196 or the touch electrode connection lines 192 and 194.

Furthermore, a color filter (not shown) may be additionally disposed on the encapsulation layer 180, and the color filter may be positioned on the touch layer 190 or between the encapsulation layer 180 and the touch layer 190.

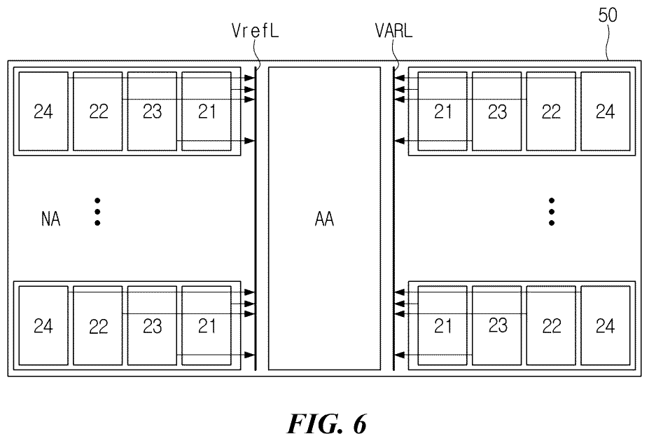

FIG. 6 is a block diagram illustrating the configuration of a gate driver according to an embodiment.

Referring to FIG. 6, the display panel 50 may include a display area AA where an image is displayed, and a non-display area around the display area AA where no image is displayed.

The display area AA includes an array of pixels PX (FIG. 1). The non-display area may include at least part of the driving unit mounted or connected. For example, the gate driver 20 may be positioned at one side of the display area AA or, as illustrated, on both sides (e.g., left or right) in the non-display area. The gate driver 20 arranged on both sides of the non-display area may be configured symmetrically (in a mirrored form). Hereinafter, the configuration will be described based on the gate driver 20 arranged on the left side of the display area AA.

The gate driver 20 may be composed of first to fourth shift registers 21 to 24. Each of the shift register 21 to 24 may include a plurality of stages of circuits connected in cascade. Each stage circuit may be composed of one or more circuit elements, such as transistors and capacitors, for generating scan signals or emission signals. The stage circuits may be connected to one or more scan lines or emission lines to output the scan signals or emission signals to the scan lines or emission lines. Each scan line or emission line may be connected to one or more pixel rows.

The first and second shift registers 21 and 22 form the scan driving circuit 20A (FIG. 1) and are configured to output scan signals SC1 and SC2 (FIG. 2). For example, the first shift register 21 may sequentially output the first scan signal SC1 through the first scan lines GL1, and the second shift register 22 may sequentially output the second scan signal SC2 through the second scan lines GL2.

The first and second shift registers 21, 22 may each be composed of stage circuits connected in a dependent manner. Each stage circuit may be connected to the corresponding scan lines GL1 and GL2 and may output the scan signals SC1 and SC2 to the scan lines GL1 and GL2.

The first and second scan signals SC1 and SC2 may be used to drive at least one transistor provided in the pixel PX. For example, the first and second scan signals SC1 and SC2 may be used to program image data DATA (FIG. 1) into the pixel PX, initialize the voltage stored in the pixel PX, or compensate for the characteristics of the circuit elements.

The third and fourth shift registers 23, 24 form the emission driving circuit 20B (FIG. 1) and are configured to output emission signals EM1, EM2 (FIG. 3). For example, the third shift register 23 may output the first emission signal EM1 through the first emission lines EL1, and the fourth shift register 24 may output the second emission signal EM2 through the second emission lines EL2.

The first and second emission signals EM1 and EM2 may be used to drive at least one transistor provided in the pixel PX. For example, the first and second emission signals EM1 and EM2 may be used to control the emission of the pixel PX.

Each of the first to fourth shift registers 21 to 24 is driven by receiving a corresponding start signal and corresponding clock signals through at least one start signal line and a plurality of clock signal lines. In this case, each clock signal may have a different phase.

The clock signals applied to the first and second shift registers 21 and 22 may be applied through adjacent clock signal lines, and the clock signals applied to the third and fourth shift registers 23 and 24 may be applied through adjacent clock signal lines. For example, the first and second shift registers 21 and 22 may receive the first and second gate clock signals applied through adjacent clock signal lines, and the third and fourth shift registers 23 and 24 may receive the first and second emission clock signals applied through adjacent clock signal lines. Here, the adjacent clock signal lines may be configured as a pair.

In one embodiment, the first shift register 21 may be positioned adjacent to the display area AA. The first shift register 21 and the second shift register 22 may be arranged sequentially farther from the display area AA.

The third shift register 23 and the fourth shift register 24 may be arranged sequentially farther from the display area AA. The fourth shift register 24 may be positioned farthest from the display area AA.

In one embodiment, the third shift register 23 may be positioned between the second shift register 22 and the fourth shift register 24, but this is not limited to this configuration.

One or more bus lines may be arranged between the gate driver 20 and the display area AA. Bus lines may include, for example, the anode reset voltage line VARL and the reference voltage line VrefL. These bus lines may be connected to pixels PX arranged in the display area AA through link lines branching from the bus lines.

In one embodiment, the bus lines may be arranged symmetrically on both sides of the display area AA. The bus lines may also be arranged on only one side of the display area AA, either the left-right or top-bottom side.

Two or more shift registers arranged adjacently may share a signal line to be supplied with power. For example, the first shift register 21 and the second shift register 22 may share a single power line, and the third shift register 23 and the fourth shift register 24 may share a single power line. However, this embodiment is not limited thereto.

The arrangement of the shift registers 21 to 24 is not limited to the illustrated configuration. The arrangement of the shift registers 21 to 24 may vary within the possible range depending on the specifications of the display panel 50 to reduce the size of the non-display area and minimize the length and amount of wiring.

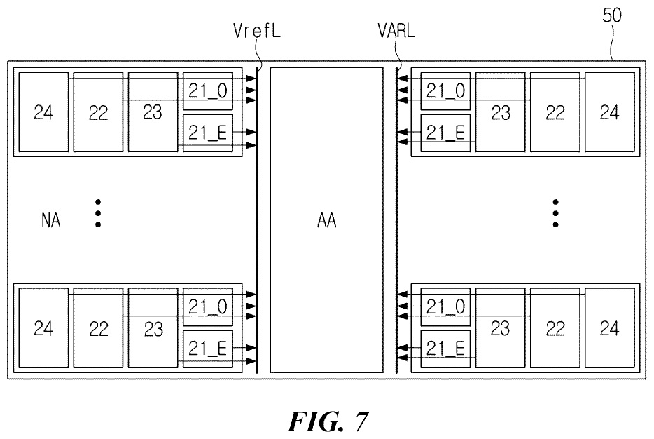

FIG. 7 is a block diagram illustrating the configuration of a gate driver according to another embodiment.

Compared to the embodiment of FIG. 6, in the embodiment of FIG. 7, the first shift register 21 may be composed of an odd-numbered first shift register 21_O and an even-numbered first shift register 21_E. As shown in the drawing, the odd-numbered first shift register 21_O and the even-numbered first shift register 21_E may be arranged on both sides of the display area AA.

When the first shift register 21 is divided into the odd-numbered first shift register 21_O and the even-numbered first shift register 21_E for driving, sufficient time required for applying the data voltage Vdata can be secured. Furthermore, by disposing the odd-numbered first shift register 21_O and the even-numbered first shift register 21_E on both sides of the display area AA, the variation in the per-pixel application time of the data voltage Vdata can be reduced. As a result, the driving of the first shift register 21 can ensure sufficient time required for applying the data voltage Vdata, and it can minimize the variation in per-pixel application time, thereby improving the image quality of the display panel.

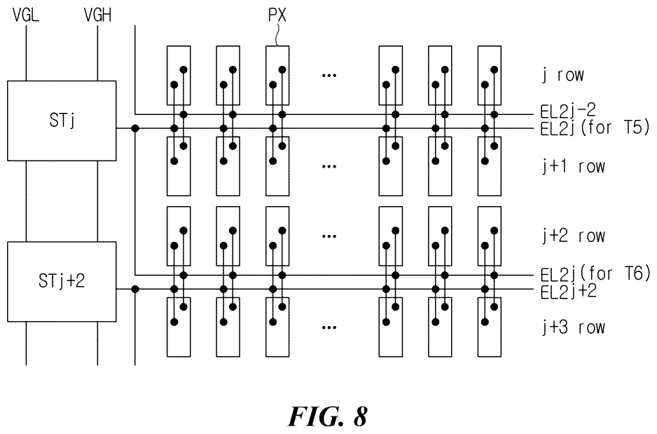

FIG. 8 is a diagram illustrating the connection relationship between the fourth shift register of FIG. 6 and a pixel.

Referring to FIG. 8, the fourth shift register 24 may include a plurality of stage circuits STj and STj+2 connected in a cascade configuration. The stage circuits STj and STj+2 may be arranged in i/2 units. Here, i refers to the total number of pixel rows, which may be a natural number. For example, the j-th stage circuit STj, the (j+2)-th stage circuit STj+2, and the (j+4)-th stage circuit (not shown) may be arranged sequentially and electrically connected.

The stage circuits STj and STj+2 may receive the gate high voltage VGH and gate low voltage VGL as inputs to drive them.

In this case, one stage circuit STj or STj+2 may be configured to apply the second emission signal EM2 to four pixel rows. That is, one stage circuit STj or STj+2 may be provided for each adjacent pair of pixel rows. For example, the j-th stage circuit STj may apply the second emission signal EM2 to the pixels PX of the j-th pixel row, the (j+1)-th pixel row, the (j+2)-th pixel row and the (j+3)-th pixel row, and the (j+2)-th stage circuit STj+2 may apply the second emission signal EM2 to the pixels PX of the (j+2)-th pixel row, the (j+3)-th pixel row, the (j+4)-th pixel row and the (j+5)-th pixel row.

In this embodiment, the emission lines EL2j, EL2j+2, and EL2j−2 extend between adjacent pixel rows. For example, the emission line EL2j, EL2j+2, and EL2j−2 may extend between the j-th and (j+1)-th pixel rows, and between the (j+2)-th and (j+3)-th pixel rows.

Specifically, the j-th second emission line EL2j extends between the j-th pixel row and the (j+1)-th pixel row. Additionally, the j-th second emission line EL2j may branch at one point and extend further between the (j+2)-th pixel row and the (j+3)-th pixel row. The j-th second emission line EL2j, which extends between pixel rows, may further extend in the horizontal direction at one or more points and be electrically connected to the plurality of pixels PX arranged in the corresponding pixel rows.

In this case, the j-th second emission line EL2j, extended between the j-th pixel row and the (j+1)-th pixel row, is connected to the gate electrodes of the second light-emission transistors T5 (FIG. 2) for the pixels PX arranged in the j-th and (j+1)-th pixel rows. Moreover, the j-th second emission line EL2j, extended between the (j+2)-th pixel row and the (j+3)-th pixel row, is connected to the gate electrodes of the compensation transistors T6 (FIG. 2) for the pixels PX arranged in the (j+2)-th and (j+3)-th pixel rows.

In this embodiment, two pixel rows each receive the second emission signal (EM2) through multiple emission lines (EL2j, EL2j+2, and EL2j−2), which are branched from a single emission line. As a result, the number of emission lines EL2j, EL2j+2, and EL2j−2 is reduced compared to independently connecting emission lines to each pixel row. Consequently, the parasitic capacitance between emission lines can be reduced. Additionally, the driving power (e.g., gate high voltage VGH and gate low voltage VGL) can be stably supplied, preventing issues like IR rising or IR drop.

Meanwhile, as shown in the illustrated embodiment, the fourth shift register 24 has a structure in which two pixel rows each receive the second emission signal EM2 through multiple emission lines (EL2j, EL2j+2, and EL2j−2) branching from a single emission line (EL2j, EL2j+2, and EL2j−2). In various embodiments, the first to third shift registers 21 to 23 (FIG. 6) and the fifth shift register, which is not shown, may be configured to apply a scan signal or emission signal to a single pixel row through one scan line or emission line. Alternatively, the first to third shift registers 21 to 23 (FIG. 6) and the fifth shift register, which is not shown, may also be configured to apply a scan signal or emission signal to two or more pixel rows through one scan line or emission line that branches.

A pixel and a display device including the pixel according to an embodiment are advantageous in reducing the size of a gate driver and a panel and improving design flexibility by compensating for the threshold voltage of a driving transistor using two scan signals and two emission signals.

A pixel and a display device including the pixel according to an embodiment are advantageous in facilitating the implementation of a narrow bezel by reducing the size of the gate driver.

A pixel and a display device including the pixel according to an embodiment are advantageous in preventing image quality degradation by minimizing coupling between emission lines.

A pixel and a display device including the pixel according to an embodiment are advantageous in minimizing current leakage by adopting a hybrid structure using an oxide semiconductor thin-film transistor.

A pixel and a display device including the pixel according to an embodiment are advantageous in preventing luminance distortion or degradation in display quality by minimizing voltage coupling between a compensation capacitor storing the threshold voltage of the driving transistor and the driving transistor.

Although embodiments of this disclosure have been described above with reference to the accompanying drawings, it will be understood that the technical configuration of this disclosure described above can be implemented in other specific forms by those skilled in the art without changing the technical concept or essential features of the present disclosure. Therefore, it should be understood that the embodiments described above are exemplary and not limited in all respects. Furthermore, the scope of the present disclosure includes those of the claims set forth below. In addition, it should be understood that all modifications or variations derived from the meaning and scope of the claims and their equivalent concept are included within the scope of the this disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A pixel comprising:
a light-emitting element;
a driving transistor connected between a high-potential driving voltage line and a first node, with a gate electrode connected to a second node;
a switching transistor connected between a data line and the second node, with a gate electrode connected to receive a first scan signal;
an initialization transistor connected between a reference voltage line and the second node, with a gate electrode connected to receive a second scan signal;
a first light-emission transistor connected between the high-potential driving voltage line and the driving transistor, with a gate electrode connected to receive a first emission signal;
a second light-emission transistor connected between the first node and the light-emitting element, with a gate electrode connected to receive a second emission signal;
a first capacitor connected between the first node and the second node;
a second capacitor with one electrode connected to the first node; and
a compensation transistor connected between the second capacitor and the reference voltage line, with a gate electrode connected to receive the second emission signal.

2. The pixel of claim 1, wherein, the pixel is disposed in an n-th pixel row, where n being a natural number, the second emission transistor is connected to receive an n-th second emission signal through an emission line connected to the n-th pixel row, and the compensation transistor is connected to receive an (n−2)-th second emission signal through an emission line connected to an (n−2)-th pixel row.

3. The pixel of claim 1, wherein, upon the first emission transistor and the second emission transistor being turned on, the compensation transistor is turned off, causing one electrode of the second capacitor to be floated.

4. The pixel of claim 1, further comprising an anode reset transistor connected between the light-emitting element and a bias voltage line, with a gate electrode connected to receive the first emission signal.

5. The pixel of claim 1, wherein, one or more of the driving transistor, the switching transistor, the initialization transistor, the first and the second emission transistors, and the compensation transistor are oxide thin-film transistors, and remaining ones of the driving transistor, the switching transistor, the initialization transistor, the first and the second emission transistors, and the compensation transistor are low temperature poly-silicon (LTPS) thin-film transistors.

6. The pixel of claim 5, wherein the second emission transistor and the compensation transistor are different types of thin-film transistors.

7. The pixel of claim 5, wherein the second emission transistor is the LTPS thin-film transistor, and the compensation transistor is the oxide thin-film transistor.

8. The pixel of claim 1, further comprising:
a substrate;
a first insulating layer disposed on the substrate;
a first semiconductor layer of a first transistor disposed on the first insulating layer;
a second insulating layer disposed on the first semiconductor layer, wherein a gate electrode of the first transistor is disposed on the second insulating layer;
a third insulating layer disposed on the gate electrode of the first transistor;
a fourth insulating layer disposed on the third insulating layer, wherein a second semiconductor layer of a second transistor is disposed on the fourth insulating layer;
a fifth insulating layer disposed on the second semiconductor layer, wherein a gate electrode of the second transistor is disposed on the fifth insulating layer; and
a sixth insulating layer disposed on the gate electrode of the second transistor, wherein source and drain electrodes of the first transistor and the second transistor are disposed on the sixth insulating layer,
wherein,
the first transistor is the compensation transistor, and the second transistor is the second emission transistor.

9. The pixel of claim 8, wherein the first capacitor comprises:
a first electrode disposed on the substrate;
a second electrode disposed on the third insulating layer; and
a third electrode disposed on the fifth insulating layer.

10. A display device comprising:
a display panel comprising a display area including pixels disposed therein and a non-display area surrounding the display area;
a gate driver configured to apply scan signals and emission signals to the pixels;
a data driver configured to apply data voltages to the pixels; and
a timing controller configured to control the driving timing of the display panel,
wherein each of the pixels comprises:
a light-emitting element;
a driving transistor connected between a high-potential driving voltage line and a first node, with a gate electrode connected to a second node;
a switching transistor connected between a data line and the second node, with a gate electrode connected to receive a first scan signal;
an initialization transistor connected between a reference voltage line and the second node, with a gate electrode connected to receive a second scan signal;
a first emission transistor connected between the high-potential driving voltage line and the driving transistor, with a gate electrode connected to receive a first emission signal;
a second emission transistor connected between the first node and the light-emitting element, with a gate electrode connected to receive a second emission signal;
a first capacitor connected between the first node and the second node;
a second capacitor with one electrode connected to the first node; and
a compensation transistor connected between the second capacitor and the reference voltage line, with a gate electrode connected to receive the second emission signal.

11. The display device of claim 10, wherein the gate driver comprises shift registers respectively disposed on left and right sides of the display area in the non-display area, and configured in a bilaterally symmetrical form with respect to each other.

12. The display device of claim 11, wherein the shift registers comprise:
a first shift register configured to output the first scan signal;
a second shift register configured to output the second scan signal;
a third shift register configured to output the first emission signal; and
a fourth shift register configured to output the second emission signal.

13. The display device of claim 12, wherein the fourth shift register is configured to output the second emission signal to four adjacent pixel rows.

14. The display device of claim 13, wherein the fourth shift register comprises:
a plurality of stage circuits connected in a cascade configuration, the plurality of stage circuits comprising a j-th stage circuit configured to apply the second emission signal to the second emission transistor of pixels disposed in a j-th pixel row and a (j+1)-th pixel row through an emission line extended between the j-th pixel row and the (j+1)-th pixel row.

15. The display device of claim 14, wherein
the j-th stage circuit is configured to apply the second emission signal to the compensation transistor of pixels disposed in a (j+2)-th pixel row and a (j+3)-th pixel row through an emission line extended between the (j+2)-th pixel row and the (j+3)-th pixel row.

16. The display device of claim 15, wherein, upon the first emission transistor and the second emission transistor being turned on, the compensation transistor is turned off, causing one electrode of the second capacitor to be floated.

17. The display device of claim 10, wherein one or more of the driving transistor, the switching transistor, the initialization transistor, the first and the second emission transistors, and the compensation transistor are oxide thin-film transistors, and remaining ones of the driving transistor, the switching transistor, the initialization transistor, the first and the second emission transistors, and the compensation transistor are low temperature poly-silicon (LTPS) thin-film transistors.

18. The display device of claim 17, wherein the second emission transistor and the compensation transistor are different types of thin-film transistors.

19. The display device of claim 17, wherein the second emission transistor is the LTPS thin-film transistor, and the compensation transistor is the oxide thin-film transistor.

20. The display device of claim 10, wherein each of the pixels further comprises an anode reset transistor connected between the light-emitting element and a bias voltage line, with a gate electrode connected to receive the first emission signal.
